(19) United States
(12) Patent Application Publication
(10) Pub. No.: US 2025/0081434 A1
(43) Pub. Date: Mar. 6, 2025

(54) SEMICONDUCTOR STRUCTURE AND PREPARATION METHOD THEREFOR

(71) Applicant: CXMT CORPORATION, Hefei (CN)

(72) Inventor: Yexiao YU, Hefei (CN)

(21) Appl. No.: 18/948,551

(22) Filed: Nov. 15, 2024

Related U.S. Application Data
(63) Continuation of application No. PCT/CN2024/078015, filed on Feb. 22, 2024.

(30) Foreign Application Priority Data
Mar. 17, 2023 (CN) 202310280042.4

(51) Int. Cl. H10B 12/00

(52) U.S. Cl. CPC H10B 12/315; H10B 12/033

(57) ABSTRACT

Provided are a semiconductor structure and a preparation method therefor. The semiconductor structure includes a substrate, a support structure, capacitor holes penetrating the support structure, and capacitor structures formed by filling the capacitor holes. The support structure includes a first support layer, and the first support layer includes first sub-holes and second sub-holes. The first sub-holes are distributed on an edge of an array region and surround the second sub-holes located inside the array region, and a projection area of each of the first sub-holes on a plane of the substrate is less than a projection area of each of the second sub-holes on the plane of the substrate.

### CROSS-REFERENCE TO RELATED APPLICATIONS

This application is a continuation of International Patent Application No. PCT/CN2024/078015, filed on Feb. 22, 2024 which claims the benefit of Chinese Patent Application No. 202310280042.4, titled “SEMICONDUCTOR STRUCTURE AND PREPARATION METHOD THEREFOR”, filed with the China National Intellectual Property Administration (CNIPA) on Mar. 17, 2023, the disclosures of which are incorporated herein by reference in their entireties.

### TECHNICAL FIELD

The present disclosure relates to the field of semiconductor technologies, and in particular, to a semiconductor structure and a preparation method therefor.

### BACKGROUND

A storage array architecture of a dynamic random access memory (DRAM) is an array of storage units including a transistor and a capacitor.

The size of the capacitor continues to reduce with that of a DRAM device. Therefore, there is an ongoing need for reducing the size of the capacitor while ensuring the performance of the capacitor.

### SUMMARY

Embodiments of the disclosure describe a semiconductor structure and a preparation method therefor.

According to some embodiments, a first aspect of the present disclosure provides a semiconductor structure, including: a substrate, the substrate including an array region; a support structure, the support structure including a first support layer; the first support layer including first sub-holes and second sub-holes; the first sub-holes being distributed on an edge of the array region, and surrounding the second sub-holes; and a projection area of each of the first sub-holes on a plane of the substrate being less than a projection area of each of the second sub-holes on the plane of the substrate; capacitor holes penetrating the support structure; and capacitor structures formed by filling the capacitor holes.

According to some embodiments, a second aspect of the present disclosure provides a preparation method for a semiconductor structure, including providing a substrate, the substrate comprising an array region; forming a stacked structure, the stacked structure comprising a first sacrificial layer and a first support layer sequentially stacked in a direction away from the substrate; forming capacitor holes penetrating the stacked structure; forming a first electrode layer on an inner wall of each of the capacitor holes; forming a first gap hole penetrating the first support layer, the first gap hole comprising first sub-holes and second sub-holes; the first sub-holes being distributed on an edge of the array region and surrounding the second sub-holes, a projection area of each of the first sub-holes on a plane of the substrate being less than a projection area of each of the second sub-holes on the plane of the substrate; and removing the first sacrificial layer through the first gap hole, to expose the first electrode layer.

The details of one or more embodiments of the present disclosure are set forth in the following accompanying drawings and description. Other features and advantages of the present disclosure will become apparent from the specification, accompanying drawings, and claims.

### BRIEF DESCRIPTION OF DRAWINGS

To describe the technical solutions in the embodiments of the present disclosure more clearly, the following briefly describes the accompanying drawings required for the embodiments. Clearly, the accompanying drawings in the following description show merely some embodiments of the present disclosure, and a person of ordinary skill in the art may still derive other drawings from these accompanying drawings without creative efforts.

FIG. 1 is a schematic diagram of a vertical cross-section of a semiconductor structure according to an embodiment of the present disclosure;

FIG. 2 is a schematic diagram of projections of a first support layer and capacitor holes on a plane of a substrate in FIG. 1;

FIG. 3 is a schematic diagram of projections of a first support layer and capacitor holes on a plane of a substrate according to another embodiment of the present disclosure;

FIG. 4 shows a phenomenon that a capacitor structure is bent after being attacked by boundary stress of an array region, where a, b, and c in the figure respectively correspond to capacitor structures in which apertures (CD) of first sub-holes are 47 nm, 51 nm, and 55 nm;

FIG. 5 is a schematic diagram of projections of a first support layer and capacitor holes on a plane of a substrate according to another embodiment of the present disclosure;

FIG. 6 is a schematic flowchart of a preparation method for a semiconductor structure according to an embodiment of the present disclosure; and

FIG. 7a to FIG. 8i are schematic structural diagrams of a semiconductor structure in a preparation procedure according to an embodiment of the present disclosure.

### DESCRIPTION OF EMBODIMENTS

Example implementations disclosed by the present disclosure are described in more detail below with reference to the accompanying drawings. Although the example implementations of the present disclosure are shown in the accompanying drawings, it should be understood that the present disclosure may be implemented in various forms without being limited by the specific implementations described herein. Instead, these implementations are provided to implement a more thorough understanding of the present disclosure and to fully convey the scope disclosed by the present disclosure to a person skilled in the art.

In the following descriptions, a large quantity of specific details are given to provide a more thorough understanding of the present disclosure. However, it is clear to a person skilled in the art that the present disclosure may be implemented without one or more of these details. In other examples, some technical features well-known in the art are not described to avoid confusion with the present disclosure. That is, not all features of actual embodiments are described herein, and well-known functions and structures are not described in detail.

In the accompanying drawings, for clarity, sizes of a layer, a region, and an element, and relative sizes thereof may be exaggerated. The same reference numerals always indicate the same elements.

It should be understood that, an element or a layer may be directly on, adjacent to, connected to, or coupled to another element or layer or there may be an intermediate element or layer when the element or the layer is referred to as “on”, “adjacent to”, “connected to”, or “coupled to” the another element or layer. Instead, there is no intermediate element or layer when an element is referred to as “directly on”, “directly adjacent to”, “directly connected to”, or “directly coupled to” another element or layer. It should be understood that, although the terms “first”, “second”, “third”, and the like may be utilized to describe various elements, components, regions, layers, and/or portions, these elements, components, regions, layers, and/or portions shall not be limited by these terms. These terms are merely utilized to distinguish one element, component, region, layer, or portion from another element, component, region, layer, or portion. Therefore, a first element, component, region, layer, or portion discussed below may be represented as a second element, component, region, layer, or portion without departing from the teachings of the present disclosure. However, when the second element, component, region, layer, or portion is discussed, it does not necessarily indicate that there is the first element, component, region, layer, or portion necessarily in the present disclosure.

Spatial relationship terms, e.g., “under”, “below”, “underlying”, “beneath”, “over”, and “above” may be utilized herein for convenience of description, to describe the relationship between one element or feature and another element or feature shown in the figures. It should be understood that in addition to the orientations shown in the figures, the spatial relationship terms are further intended to include different orientations of components in use and operation. An element or a feature described as “below another element” is oriented to be “above” the another element or feature, for example, if the components in the accompanying drawings are flipped. Therefore, the example terms “below” and “beneath” may include orientations of being above and being below. The component may be otherwise oriented (rotated by 90 degrees or oriented in another manner), and the spatial descriptors utilized herein are interpreted accordingly.

The terms utilized herein are intended merely to describe specific embodiments and are not construed as a limitation on the present disclosure. As utilized herein, the singular forms “a/an”, “one”, and “the” are also intended to include plural forms unless the context clearly indicates otherwise. It should also be understood that the terms “constitute” and/or “include” are utilized in the specification to determine the presence of the feature, integer, step, operation, element, and/or component, but not rule out the presence or addition of one or more other features, integers, steps, operations, elements, components, and/or groups. As utilized herein, the term “and/or” includes any and all combinations of the related items listed. All value ranges in this specification include endpoint values.

As the size of a dynamic random access memory (DRAM) continues to reduce and the degree of integration continues to increase, the size of a capacitor structure continues to reduce, resulting in a continuous increase in the aspect ratio of the capacitor structure, which increases a risk of bending of the capacitor structure after the capacitor structure is attacked by boundary stress of an array region.

Based on this, the following technical solutions are proposed in the present disclosure.

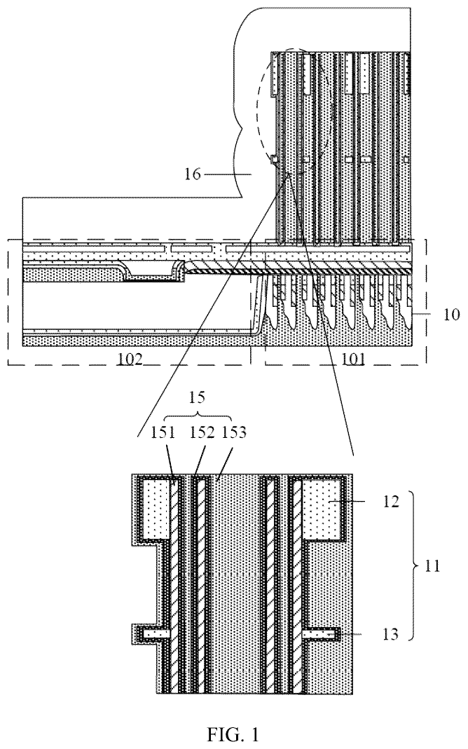

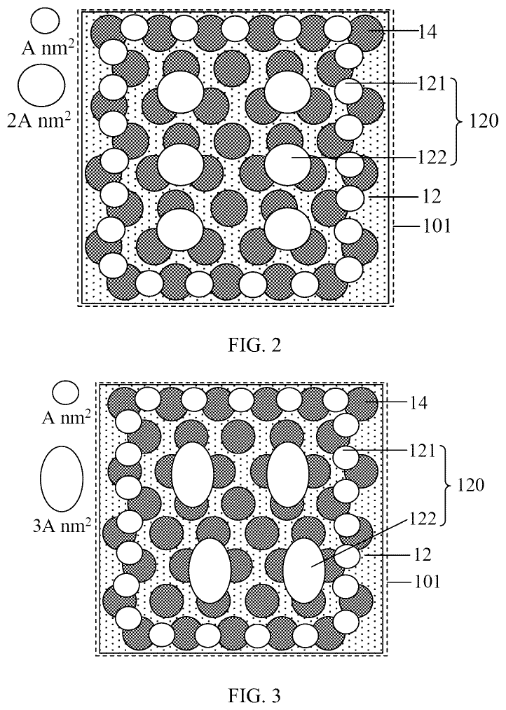

Embodiments of the present disclosure provide a semiconductor structure. FIG. 1 is a schematic diagram of a vertical cross-section of a semiconductor structure according to an embodiment of the present disclosure; FIG. 2 is a schematic diagram of projections of a first support layer 12 in FIG. 1 and capacitor holes 14 on a plane of a substrate 10; and FIG. 3 is a schematic diagram of projections of a first support layer 12 and capacitor holes 14 on a plane of a substrate 10 according to another embodiment of the present disclosure. Referring to FIG. 1 and FIG. 2, the semiconductor structure includes:
a substrate 10, the substrate 10 including an array region 101;
a support structure 11, the support structure 11 including a first support layer 12;
the first support layer 12 including multiple first sub-holes 121 and multiple second sub-holes 122; the first sub-holes 121 being distributed on an edge of the array region 101, and surrounding the second sub-holes 122; and a projection area of each of the first sub-holes 121 on the plane of the substrate 10 being less than a projection area of each of the second sub-holes 122 on the plane of the substrate 10 (refer to FIG. 2);
multiple capacitor holes 14 penetrating the support structure 11; and
multiple capacitor structures 15 formed by filling the capacitor holes 14.

Herein, the plane of the substrate 10 is a plane on which the substrate 10 is located. The array region 101 and a peripheral region 102 are included on the substrate 10. The substrate 10 may be a silicon substrate, a germanium substrate, a silicon germanium substrate, a silicon carbide substrate, a silicon on insulator (SOI) substrate, a germanium on insulator (GOI) substrate, or the like, may be a substrate including another element semiconductor or a compound semiconductor, e.g., a glass substrate or a III-V group compound substrate (e.g., a gallium nitride substrate or a gallium arsenide substrate), may be a stacked structure, e.g., an Si/SiGe structure, or may be another epitaxial structure, e.g., a silicon germanium on insulator (SGOI) structure.

In an actual operation, the capacitor hole 14, the first sub-hole 121, and the second sub-hole 122 may be in a shape of a circle, an oval, or a rectangle. This is not specifically limited herein. In addition, the shapes of the first sub-holes 121 and the second sub-holes 122 may be the same or different.

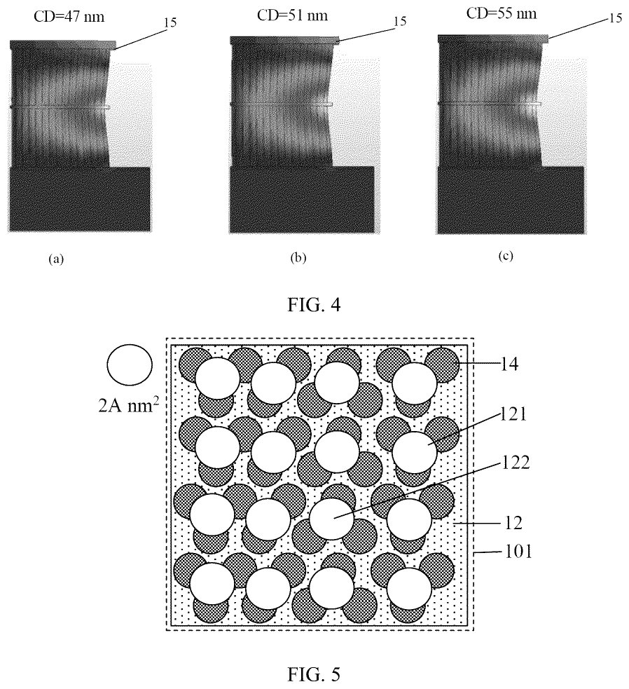

FIG. 4 shows a phenomenon that a capacitor structure 15 is bent after being attacked by boundary stress of the array region, where a, b, and c in the figure respectively correspond to capacitor structures 15 in which apertures (CD) of first sub-holes 121 are 47 nm, 51 nm, and 55 nm. It may be seen that, as the aperture diameter of the first sub-hole 121 increases, that is, the projection area of the first sub-hole 121 on the plane of the substrate 10 increases, the boundary stress of the array region to which the capacitor structure 15 is subjected increases, and the bending problem becomes more serious.

Therefore, in this embodiment of the present disclosure, as shown in FIG. 2, by reducing the projection area, of the first sub-hole 121 located on the edge of the array region 101, on the plane of the substrate 10, the boundary stress of the array region to which the capacitor structure 15 is subjected can be reduced, thereby alleviating the bending problem of the capacitor structure 15, and improving the stability of the capacitor structure 15. In addition, the second sub-hole 122 surrounded by the first sub-hole 121 can still maintain a relatively large area, to ensure that the capacitor structure 15 has a relatively large filling area, and the capacitor structure 15 has a relatively large capacitance value.

It should be understood that, to facilitate preparation of the multiple first sub-holes 121 and the multiple second sub-holes 122, enable the first support layer 12 including the first sub-holes 121 and the second sub-holes 122 to support the capacitor structure 15 more evenly and balanced, and further reduce the boundary stress of the array region to which the capacitor structure 15 is subjected, layouts, shapes, and the like of the multiple first sub-holes 121 and the multiple second sub-holes 122 may be designed in a standardized manner.

For example, in an embodiment, referring to FIG. 2, a projection of the first sub-hole 121 overlaps projections of two of the capacitor holes 14, and a projection of the second sub-hole 122 overlaps projections of three of the capacitor holes 14. Herein, the first sub-holes 121 are in the same shape of a circle, and the second sub-holes 122 are also in the same shape of a circle. Herein, the ratio of the projection area of the second sub-hole 122 on the plane of the substrate 10 to the projection area of the first sub-hole 121 on the plane of the substrate 10 is in a range of 1.8-2.2. In some embodiments, referring to FIG. 2, the projection area of the second sub-hole 122 on the plane of the substrate 10 is twice the projection area of the first sub-hole 121 on the plane of the substrate 10.

In another embodiment, referring to FIG. 3, a projection of the first sub-hole 121 overlaps projections of two of the capacitor holes 14, and a projection of the second sub-hole 122 overlaps projections of four of the capacitor holes 14. Herein, the first sub-holes 121 are in the same shape of an oval, and the second sub-holes 122 are also in the same shape of an oval. Herein, the ratio of the projection area of the second sub-hole 122 on the plane of the substrate 10 to the projection area of the first sub-hole 121 on the plane of the substrate 10 is in a range of 2.8-3.2. In some embodiments, referring to FIG. 3, the projection area of the second sub-hole 122 on the plane of the substrate 10 is three times the projection area of the first sub-hole 121 on the plane of the substrate 10.

In an actual operation, in a direction perpendicular to the plane of the substrate 10, there is a case in which a projection of a part of the capacitor holes 14 on the plane of the substrate 10 does not overlap the projection of the second sub-hole 122 on the plane of the substrate 10. Both the capacitor hole 14 and other capacitor holes 14 surrounding the capacitor hole 14 are connected through the first support layer 12, which further improves the stability of the capacitor structure 15. Certainly, projections of all the capacitor holes 14 in the array region 101 on the plane of the substrate 10 may alternatively overlap projections of the second sub-holes 122 on the plane of the substrate 10. This is not specifically limited herein. The projection of the first sub-hole 121 on the plane of the substrate 10 may not be limited to overlapping those of only two capacitor holes 14. The projection of the second sub-hole 122 on the plane of the substrate 10 may not be limited to overlapping those of only three or four capacitor holes 14, or may overlap projections of another quantity of capacitor holes 14 on the plane of the substrate 10. This is not specifically limited herein.

FIG. 5 shows an example of an implementation of a related technology. Projection areas of the first sub-hole 121 and the second sub-hole 122 on the plane of the substrate 10 are the same, areas of each first sub-hole 121 and each second sub-hole 122 are 2 A nm², and a total projection area of the multiple first sub-holes 121 and the multiple second sub-holes 122 on the plane of the substrate 10 is 32 A nm². In the embodiments of the present disclosure shown in FIG. 2 and FIG. 3, a total projection area of the multiple first sub-holes 121 and the multiple second sub-holes 122 on the plane of the substrate 10 is 35 A nm². It can be learned that the total projection area, on the plane of the substrate 10, of the multiple first sub-holes 121 and the multiple second sub-holes 122 of the semiconductor structure provided in this embodiment of the present disclosure only slightly increases, and in this case, a filling area of the first support layer 12 only slightly decreases. Therefore, the support effect of the support structure 11 is not greatly damaged.

In some embodiments, referring to FIG. 1, a second support layer 13 is further included in the support structure 11, the first support layer 12 is located on the upper surface of the substrate 10, and the second support layer 13 is disposed parallel to the first support layer 12. Specifically, first sub-holes 121 and second sub-holes 122 may be also included at the second support layer 13. The materials of the first support layer 12 and the second support layer 13 may include but are not limited to nitrides such as silicon nitride, silicon carbide nitride, silicon oxynitride, or silicon boron nitride.

The support structure 11 refers to a functional layer playing a supporting role in the capacitor structure 15. The stability of the capacitor structure 15 is directly determined by the stability of the support structure 11. It should be noted that in some other embodiments, more than two support layers may be included in the support structure 11. For example, a third support layer located under the second support layer 13 is further included. By providing multiple support layers, a supporting role on the capacitor structure 15 can be improved.

In some embodiments, as shown in FIG. 2, the multiple capacitor holes 14 are arranged in a hexagonal pattern (6F2), and projections of adjacent six capacitor holes 14 on the plane of the substrate 10 are arranged in a pattern of a regular hexagon. Each vertex angle of the regular hexagon is provided with one capacitor hole 14, and the center of the regular hexagon is provided with one capacitor hole 14. An arrangement manner of the capacitor holes 14 is a hexagonal closest packed (HCP) structure. A quantity of capacitor structures 15 in a dynamic random access memory is determined by a quantity of the capacitor holes 14. Based on the hexagonal closest packed structure, closely arranged capacitor structures 15 can be obtained, thereby increasing the arrangement density and the degree of integration of the capacitor structures 15 in the dynamic random access memory, and further ensuring the data storage capacity of the dynamic random access memory.

In some embodiments, referring to FIG. 1, the capacitor structure 15 includes:
a first electrode layer 151, covering a sidewall and the bottom surface of the capacitor hole 14;
a capacitor dielectric layer 152, covering bare surfaces of the first electrode layer 151 and the support structure 11, and covering sidewalls and the bottom surfaces of the first sub-hole 121 and the second sub-hole 122; and
a second electrode layer 153, covering the surface of the capacitor dielectric layer 152.

The capacitor dielectric layer 152 further covers the sidewalls and the bottom surfaces of the first sub-hole 121 and the second sub-hole 122. Therefore, as the total projection area of the multiple first sub-holes 121 and the multiple second sub-holes 122 on the plane of the substrate 10 increases, the capacitance value of the capacitor structure 15 further increases.

In some specific embodiments, the materials of the first electrode layer 151 and the second electrode layer 153 may include a compound formed by one or two of metal nitride and metal silicide, e.g., titanium nitride, titanium silicide, nickel silicide, and titanium silicon nitride (TiSixNy). The capacitor dielectric layer 152 may be made of a material having a relatively high dielectric constant, e.g., a high dielectric material (High-k). A dielectric constant of the high dielectric material is greater than a dielectric constant of silicon dioxide. The high dielectric material is insulated, and has a relatively high dielectric constant value. When other conditions are the same, the high dielectric constant may bring a higher capacitance value. The material of the capacitor dielectric layer 152 includes but is not limited to silicon oxynitride.

In some embodiments, referring to FIG. 1, a part of a sidewall of the first electrode layer 151 is connected to the first support layer 12, and a part of the sidewall of the first electrode layer 151 is connected to the second support layer 13. The thickness of the first support layer 12 is greater than the thickness of the second support layer 13.

In some specific embodiments, the first support layer 12 is connected to the top of the first electrode layer 151, and the second support layer 13 is connected to the middle of the first electrode layer 151. In this way, the support layers arranged at intervals from bottom to top can provide a stable and balanced supporting force for the capacitor structure 15, thereby ensuring the stability of the capacitor structure 15. In addition, the thickness of the first support layer 12 is greater than the thickness of the second support layer 13, so that the support stability on the top of the first electrode layer 151 is improved, and the top of the first electrode layer 151 does not collapse and bridge, thereby preventing a problem of a short circuit of the capacitor structure 15.

In some embodiments, referring to FIG. 1, the semiconductor structure further includes:
a protective layer 16, the protective layer 16 covering the top and a sidewall of the capacitor structure 15, where the material of the protective layer 16 includes polysilicon.

When the lateral support structure 11 is added to improve the stability of the capacitor structure 15, an irregular sidewall of the capacitor structure 15 is formed. Consequently, a crack is easily formed at the sidewall of the capacitor structure 15 when another material is deposited, causing a short circuit phenomenon. Therefore, the protective layer 16 is added to the top and the sidewall of the capacitor structure 15, which effectively avoids a defect problem caused by the irregular sidewall of the capacitor structure 15, and improves the reliability of the semiconductor structure.

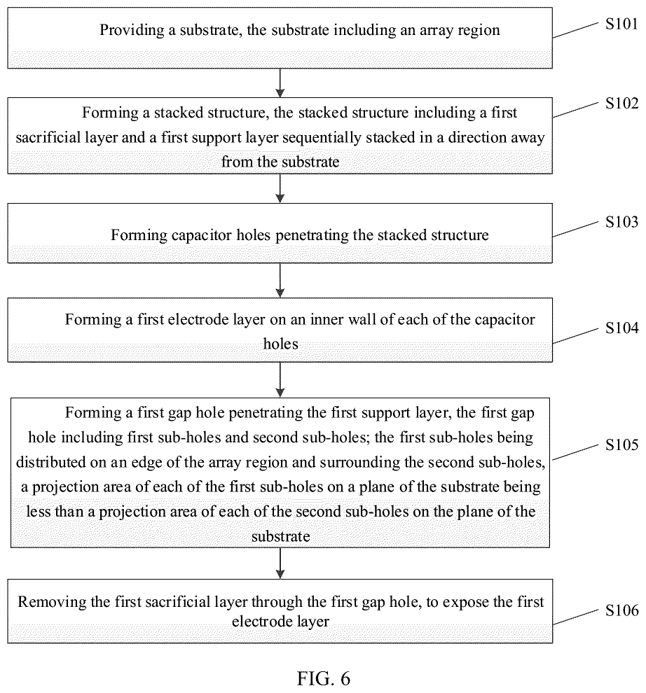

An embodiment of the present disclosure further provides a preparation method for a semiconductor structure. FIG. 6 is a schematic flowchart of a preparation method for a semiconductor structure according to an embodiment of the present disclosure. As shown in FIG. 6, the method includes the following steps:

In the step of S101, a substrate 10 is provided, the substrate 10 including an array region 101.

In the step of S102, a stacked structure 20 is formed, the stacked structure 20 including a first sacrificial layer 21 and a first support layer 12 sequentially stacked in a direction away from the substrate 10.

In the step of S103, multiple capacitor holes 14 penetrating the stacked structure 20 are formed.

In the step of S104, a first electrode layer 151 is formed on an inner wall of the capacitor hole 14.

In the step of S105, a first gap hole 120 penetrating the first support layer 12 is formed, the first gap hole 120 including multiple first sub-holes 121 and multiple second sub-holes 122; the first sub-holes 121 being distributed on an edge of the array region 101 and surrounding the second sub-holes 122, a projection area of each of the first sub-holes 121 on a plane of the substrate 10 being less than a projection area of each of the second sub-holes 122 on the plane of the substrate 10.

In the step of S106, the first sacrificial layer 21 is removed through the first gap hole 120, to expose the first electrode layer 151.

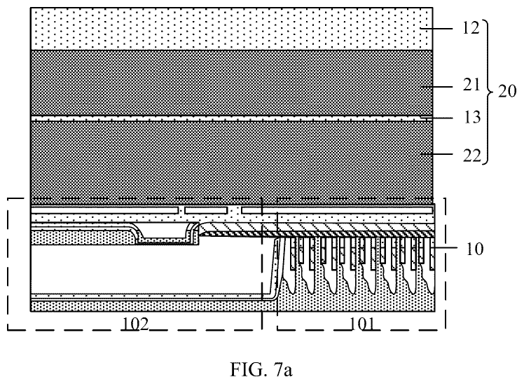

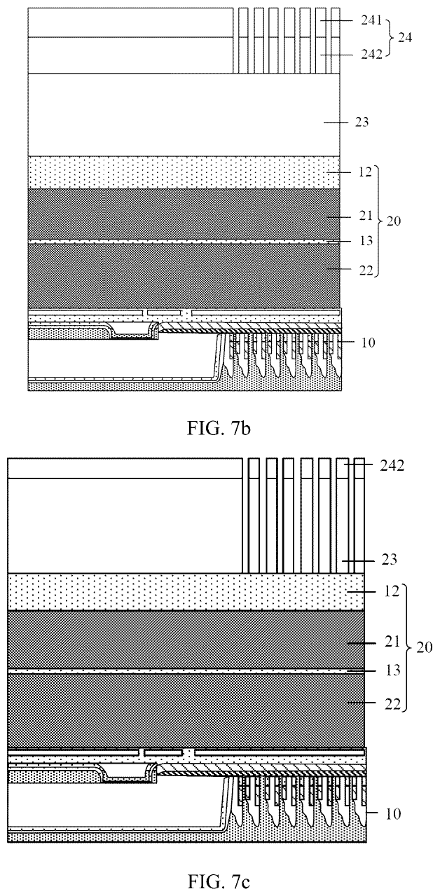

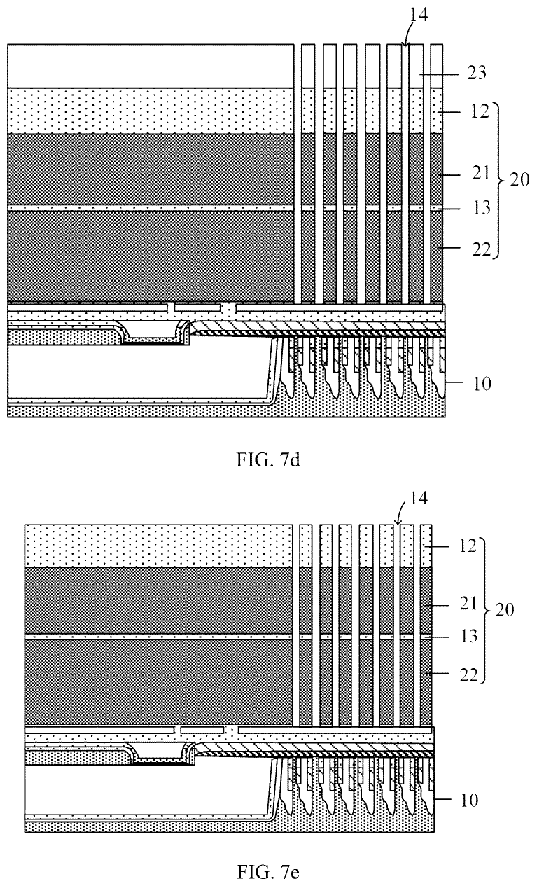

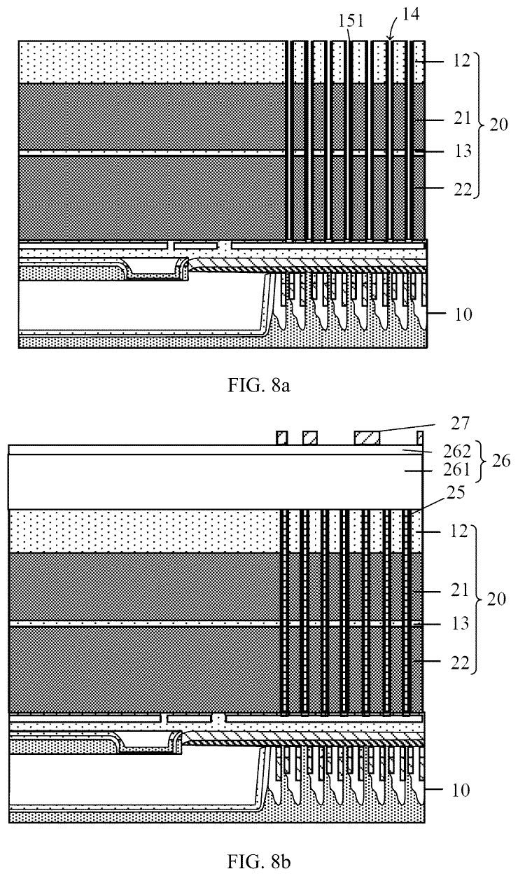

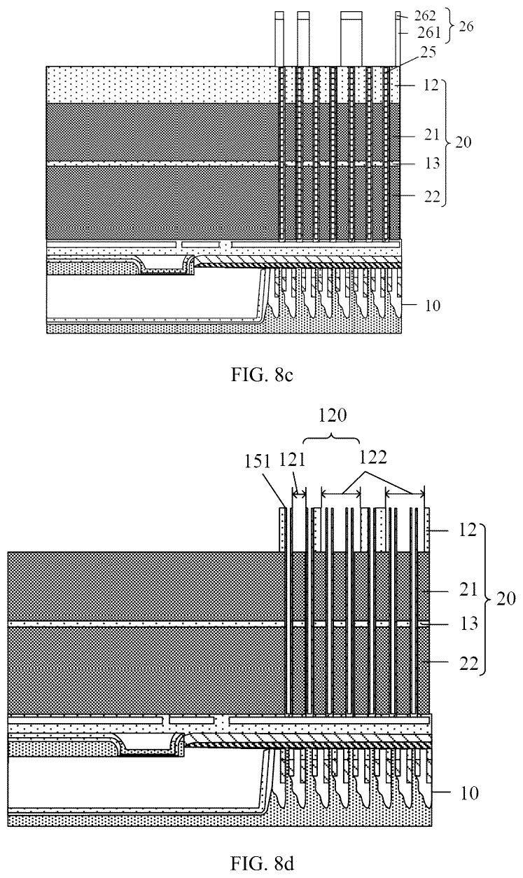

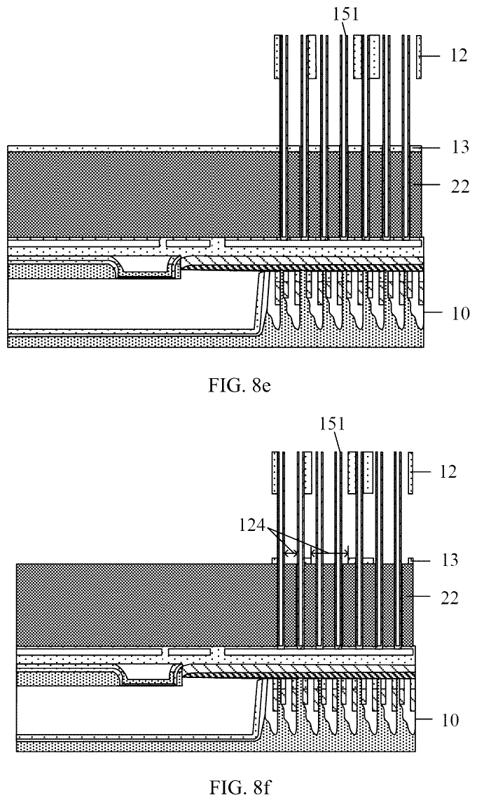

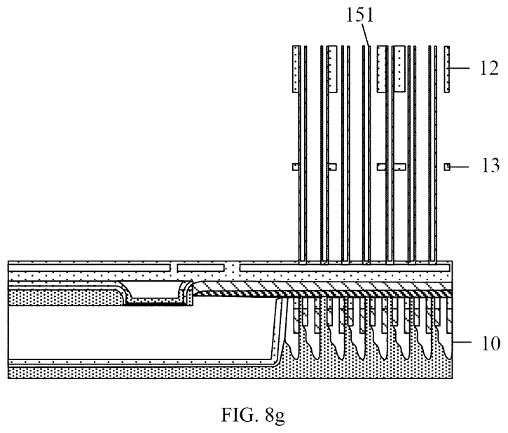

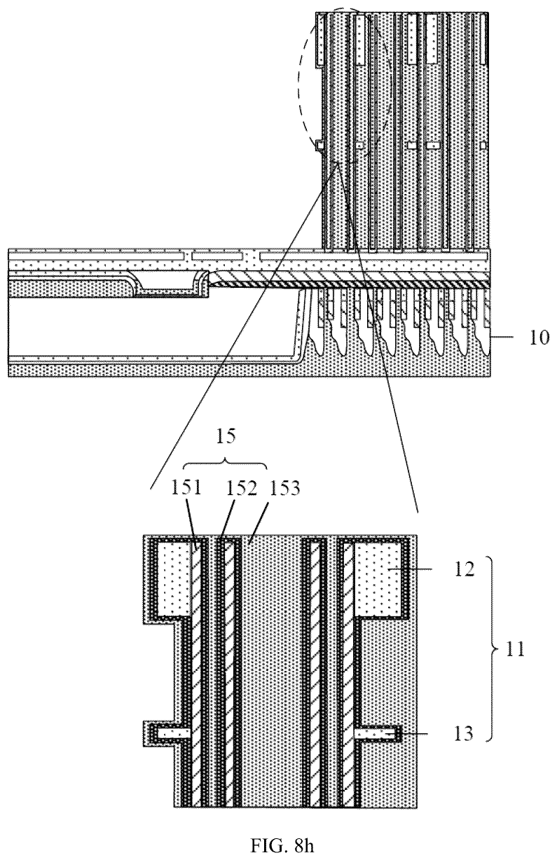

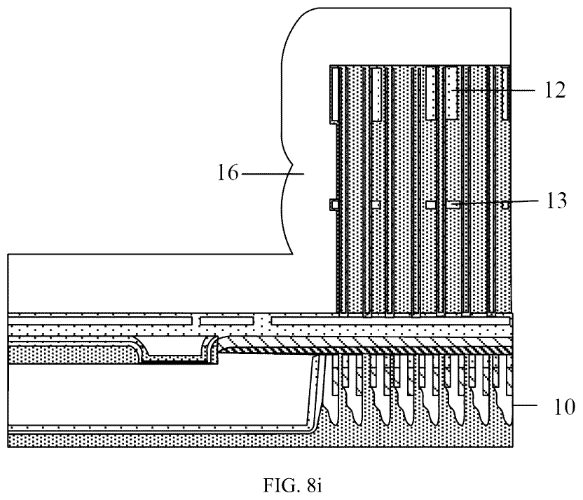

FIG. 7a to FIG. 8i are schematic structural diagrams of a semiconductor structure in a preparation procedure according to an embodiment of the present disclosure. With reference to FIG. 7a to FIG. 8i, the following further describes the preparation method for a semiconductor structure provided in the embodiments of the present disclosure.

First, referring to FIG. 7a, step S101 is performed: A substrate 10 is provided, the substrate 10 including an array region 101; and step S102 is performed: A stacked structure 20 is formed, the stacked structure 20 including a first sacrificial layer 21 and a first support layer 12 sequentially stacked in a direction away from the substrate 10.

In an actual operation, that a stacked structure 20 is formed further includes the step as follows. A second sacrificial layer 22 and a second support layer 13 that are located between the substrate 10 and the first sacrificial layer 21 are formed; the second sacrificial layer 22 being located between the substrate 10 and the second support layer 13.

Herein, the array region 101 and a peripheral region 102 are included on the substrate 10. The substrate 10 may be a silicon substrate, a germanium substrate, a silicon germanium substrate, a silicon carbide substrate, a silicon on insulator (SOI) substrate, a germanium on insulator (GOI) substrate, or the like, may be a substrate including another element semiconductor or a compound semiconductor, e.g., a glass substrate or a III-V group compound substrate (e.g., a gallium nitride substrate or a gallium arsenide substrate), may be a stacked structure, e.g., an Si/SiGe structure, or may be another epitaxial structure, e.g., a silicon germanium on insulator (SGOI) structure.

Forming the first sacrificial layer 21, the first support layer 12, the second sacrificial layer 22, and the second support layer 13 may be implemented by one or more processes of physical vapor deposition (PVD), chemical vapor deposition (CVD), or atomic layer deposition (ALD). The materials of the first sacrificial layer 21 and the second sacrificial layer 22 include but are not limited to any one of phosphosilicate glass (PSG), borophosphosilicate glass (BPSG), or another silicon oxide. The materials of the first support layer 12 and the second support layer 13 include but are not limited to nitrides such as silicon nitride, silicon carbide nitride, silicon oxynitride, or silicon boron nitride. The materials of the second sacrificial layer 22 and the first sacrificial layer 21 may be the same or different, and the materials of the second support layer 13 and the first support layer 12 may be the same or different. Specifically, the materials of the first sacrificial layer 21 and the second sacrificial layer 22 are silicon oxide, and the materials of the first support layer 12 and the second support layer 13 are silicon nitride.

It should be noted that in some other embodiments, multiple layer groups including sacrificial layers and support layers may be included on the stacked structure 20, for example, a third support layer and a third sacrificial layer that are located between the substrate 10 and the second sacrificial layer 22 are further included. By disposing the multiple layer groups, multiple support layers can be provided, thereby providing a stable and balanced supporting role for a subsequently formed capacitor structure 15. However, it is not advisable to dispose too many layer groups.

After the stacked structure 20 is formed, referring to FIG. 7b to FIG. 7e, step S103 is performed: Multiple capacitor holes 14 penetrating the stacked structure 20 are formed.

Specifically, referring to FIG. 7b to FIG. 7e, the capacitor holes 14 may be formed by the following steps.

First, a first mask layer 23, a second mask layer 24, and a first photoresist layer (not shown in the figure) with a first opening pattern are sequentially formed on the stacked structure 20. Then, the first opening pattern is transferred to the second mask layer 24 to form a patterned second mask layer 24, and the patterned second mask layer 24 is utilized as a mask to etch the first mask layer 23, to form a patterned first mask layer 23. Finally, the patterned first mask layer 23 is utilized as a mask to etch the stacked structure 20 and a part of the substrate 10, to form the multiple capacitor holes 14.

The material of the first mask layer 23 includes but is not limited to polysilicon. A first sublayer 241 and a second sublayer 242 are included at the second mask layer 24, the material of the first sublayer 241 includes but is not limited to amorphous carbon, and the material of the second sublayer 242 includes but is not limited to silicon oxide.

In some specific embodiments, referring to FIG. 7e, the capacitor hole 14 penetrates the stacked structure 20 and extends into the substrate 10, thereby facilitating a good electrical connection between the subsequently formed capacitor structure 15 and a capacitor contact structure, to increase a device yield. Referring to FIG. 2, in the multiple capacitor holes 14, projections of adjacent six capacitor holes 14 on the plane of the substrate 10 are arranged in a pattern of a regular hexagon. Each vertex angle of the regular hexagon is provided with one capacitor hole 14, and the center of the regular hexagon is provided with one capacitor hole 14. An arrangement manner of the capacitor holes 14 is a hexagonal closest packed (HCP) structure. A quantity of capacitor structures 15 in a dynamic random access memory is determined by a quantity of the capacitor holes 14. Based on the hexagonal closest packed structure, closely arranged capacitor structures 15 can be subsequently obtained, thereby increasing the arrangement density and the degree of integration of the capacitor structures 15 in the dynamic random access memory, and further ensuring the data storage capacity of the dynamic random access memory.

After the capacitor hole 14 is formed, referring to FIG. 7e, the patterned first mask layer 23 with a preset thickness may be removed. It should be understood that in some other embodiments, referring to FIG. 7d, the first mask layer 23 may alternatively be retained, to serve as an additional support structure 11. Therefore, an etching process required for removing the patterned mask layer is omitted, thereby reducing process steps, and reducing the process difficulty, and the hard characteristic of the first mask layer 23 is cleverly utilized, to increase the degree of firmness of the support layer, and improve the stability of the capacitor structure 15. The material of the first mask layer 23 is polysilicon. In addition, the retained patterned first mask layer 23 with the preset thickness may further increase the height of the capacitor structure 15, and increase the capacitance value of the capacitor structure 15.

Next, referring to FIG. 8a, step S104 is performed: A first electrode layer 151 is formed on an inner wall of the capacitor hole 14.

The first electrode layer 151 may be formed by one or more processes of physical vapor deposition, chemical vapor deposition, or atomic layer deposition. The material of the first electrode layer 151 includes but is not limited to metal nitride or metal silicide, e.g., titanium nitride. The top of the first electrode layer 151 is flush with the top of the first support layer 12.

After the first electrode layer 151 is formed, referring to FIG. 8b to FIG. 8d, step S105 is performed: A first gap hole 120 penetrating the first support layer 12 is formed, the first gap hole 120 including multiple first sub-holes 121 and multiple second sub-holes 122; the first sub-holes 121 being distributed on an edge of the array region 101 and surrounding the second sub-holes 122, a projection area of each of the first sub-holes 121 on a plane of the substrate 10 being less than a projection area of each of the second sub-holes 122 on the plane of the substrate 10.

Referring to FIG. 8b to FIG. 8d, specific steps of forming the first gap hole 120 include the following: A filling layer 25 is deposited in the capacitor hole 14, and then a third mask layer 26 covering the upper surfaces of the first support layer 12, the first electrode layer 151, and the filling layer 25, and a second photoresist layer 27 with a second opening pattern and a third opening pattern are sequentially formed; the second opening pattern and the third opening pattern are transferred to the third mask layer 26, and a patterned third mask layer 26 is utilized as a mask to etch the first support layer 12, to form the multiple first sub-holes 121 and the second sub-holes 122; and the filling layer 25 is removed.

The material of the filling layer 25 includes but is not limited to amorphous carbon. The filling layer 25 in the capacitor hole 14 with a relatively high aspect ratio may be removed by an ashing process of oxygen, ozone, or ultraviolet. A third sublayer 261 and a fourth sublayer 262 are included at the third mask layer 26, the material of the third sublayer 261 includes but is not limited to amorphous carbon, and the material of the fourth sublayer 262 includes but is not limited to a spin coating hard mask, and the fourth sublayer 262 may be formed by a spin coating process.

In some embodiments, the ratio of the projection area of the second sub-hole 122 on the plane of the substrate 10 to the projection area of the first sub-hole 121 on the plane of the substrate 10 is in a range of 1.8-2.2. In some embodiments, referring to FIG. 2, the projection area of the second sub-hole 122 on the plane of the substrate 10 is twice the projection area of the first sub-hole 121 on the plane of the substrate 10, a projection of the first sub-hole 121 overlaps projections of two of the capacitor holes 14, and a projection of the second sub-hole 122 overlaps projections of three of the capacitor holes 14.

In some other embodiments, the ratio of the projection area of the second sub-hole 122 on the plane of the substrate 10 to the projection area of the first sub-hole 121 on the plane of the substrate 10 is in a range of 2.8-3.2. In some embodiments, referring to FIG. 3, the projection area of the second sub-hole 122 on the plane of the substrate 10 is three times the projection area of the first sub-hole 121 on the plane of the substrate 10, a projection of the first sub-hole 121 overlaps projections of two of the capacitor holes 14, and a projection of the second sub-hole 122 overlaps projections of four of the capacitor holes 14.

In some other embodiments, the projection of the first sub-hole 121 on the plane of the substrate 10 may not be limited to overlapping those of only two capacitor holes 14. The projection of the second sub-hole 122 on the plane of the substrate 10 may not be limited to overlapping those of only three or four capacitor holes 14, or may overlap projections of another quantity of capacitor holes 14 on the plane of the substrate 10. This is not specifically limited herein.

In an actual operation, by limiting a location relationship between the projections of each of the first sub-hole 121 and the second sub-hole 122 and the capacitor hole 14 on the plane of the substrate 10, the projection areas of the first sub-hole 121 and the second sub-hole 122 on the plane of the substrate 10 can be further limited, a layout manner of the multiple first sub-holes 121 and the second sub-holes 122 can be designed in a more standardized manner, a total projection area of the first gap hole 120 on the plane of the substrate 10 is calculated and adjusted, to shorten a design period, and a better opening solution is obtained.

In some specific embodiments, referring to FIG. 2, in a direction perpendicular to the plane of the substrate 10, a projection of a part of the capacitor holes 14 in the array region 101 on the plane of the substrate 10 does not overlap the projection of the second sub-hole 122 on the plane of the substrate 10. Both the capacitor hole 14 and other capacitor holes 14 surrounding the capacitor hole 14 are connected through the first support layer 12, which can further improve the stability of the subsequently formed capacitor structure 15. Certainly, projections of all the capacitor holes 14 in the array region 101 on the plane of the substrate 10 may alternatively overlap projections of the second sub-holes 122 on the plane of the substrate 10.

In some embodiments, because the projection area of the first sub-hole 121 on the plane of the substrate 10 is less than the projection area of the second sub-hole 122 on the plane of the substrate 10, the second sub-hole 122 surrounded by the first sub-hole 121 has relatively large layout space inside the array region 101. Therefore, the second sub-hole 122 surrounded by the first sub-hole 121 may still maintain a relatively large area, to ensure that the total projection area of the first gap hole 120 on the plane of the substrate 10 is relatively large, thereby avoiding a decrease in the efficiency of subsequently removing the first sacrificial layer 21 through the first gap hole 120.

Specifically, referring to FIG. 2, FIG. 3, and FIG. 5, the projection areas of the first sub-hole 121 and the second sub-hole 122 on the plane of the substrate 10 are the same in FIG. 5, areas of each first sub-hole 121 and each second sub-hole 122 are 2 A nm², and a total projection area of the multiple first sub-holes 121 and the multiple second sub-holes 122 on the plane of the substrate 10 is 32 A nm². In the embodiments of the present disclosure shown in FIG. 2 and FIG. 3, a total projection area of the multiple first sub-holes 121 and the multiple second sub-holes 122 on the plane of the substrate 10 is 35 A nm². It can be learned that a total projection area, on the plane of the substrate 10, of multiple first gap holes 120 of the semiconductor structure provided in this embodiment of the present disclosure only slightly increases, and in this case, a filling area of the first support layer 12 only slightly decreases. Therefore, the support effect of the support structure 11 is not greatly damaged.

Next, referring to FIG. 8e, step S106 is performed: The first sacrificial layer 21 is removed through the first gap hole 120, to expose the first electrode layer 151.

In an actual operation, the first sacrificial layer 21 may be removed by a wet etching process. For example, an etching solution, e.g., an acid solution, is injected into the first gap hole 120, and the first sacrificial layer 21 is dissolved by the acid solution, to completely remove the first sacrificial layer 21, thereby exposing the second support layer 13. The wet etching process is isotropic, so that the entire first sacrificial layer 21 can be removed through the first gap hole 120. It should be noted that the first sacrificial layer 21, the first support layer 12, and the first electrode layer 151 have a relatively large etching selectivity ratio. Therefore, when the first sacrificial layer 21 is removed, the first support layer 12 and the first electrode layer 151 are little damaged or not damaged at all.

In some embodiments, referring to FIG. 8f and FIG. 8g, the preparation method provided in this embodiment of the present disclosure further includes the steps as follows. A second gap hole 124 penetrating the second support layer 13 is formed, where a projection of the second gap hole 124 on the plane of the substrate 10 is located in a projection of the first gap hole 120 on the plane of the substrate 10; and
the second sacrificial layer 22 is removed through the second gap hole 124, to expose a remaining part of the first electrode layer 151.

It may be understood that the second gap hole 124 is formed through the first gap hole 120. Therefore, the second gap hole 124 may be formed under each first gap hole 120, to form the second gap holes 124 corresponding to each first gap holes 120, so that the second gap hole 124 is identical to the first gap hole 120 in location and quantity. Alternatively, the second gap hole 124 may be formed only under a part of the first gap holes 120, so that the second gap hole 124 is different from the first gap hole 120 in quantity.

In some embodiments, referring to FIG. 8h, the preparation method provided in this embodiment of the present disclosure further includes the step as follows.

A capacitor dielectric layer 152 covering the first electrode layer 151 and a second electrode layer 153 are sequentially formed, to form the capacitor structure 15.

In an actual operation, processes of forming the capacitor dielectric layer 152 and the second electrode layer 153 may be one or more processes of physical vapor deposition, chemical vapor deposition, or atomic layer deposition. The materials of the first electrode layer 151 and the second electrode layer 153 may include a compound formed by one or two of metal nitride and metal silicide, e.g., titanium nitride, titanium silicide, nickel silicide, and titanium silicon nitride (TiSixNy). The capacitor dielectric layer 152 may be made of a material having a relatively high dielectric constant, e.g., silicon oxynitride, titanium dioxide, or aluminium oxide.

In some embodiments, referring to FIG. 8i, the preparation method provided in this embodiment of the present disclosure further includes the step as follows.

A protective layer 16 is formed, the protective layer 16 covering the top and a sidewall of the capacitor structure 15.

When the lateral support structure 11 is added to improve the stability of the capacitor structure 15, an irregular sidewall of the capacitor structure 15 is formed. Consequently, a crack is easily formed at the sidewall of the capacitor structure 15 when another material is deposited, causing a short circuit phenomenon. Therefore, the protective layer 16 is added to the top and the sidewall of the capacitor structure 15, which effectively avoids a defect problem caused by the irregular sidewall of the capacitor structure 15, and improves the reliability of the semiconductor structure.

In an actual operation, a process of forming the protective layer 16 may be one or more processes of physical vapor deposition, chemical vapor deposition, or atomic layer deposition, and the material of the protective layer 16 includes but is not limited to polysilicon.

In conclusion, in the embodiments of the present disclosure, by reducing the projection area, of the first sub-hole 121 located on the edge of the array region 101, on the plane of the substrate 10, the boundary stress of the array region to which the capacitor structure 15 is subjected can be reduced, thereby alleviating the bending problem of the capacitor structure 15, and improving the stability of the capacitor structure 15. In addition, the second sub-hole 122 surrounded by the first sub-hole 121 can still maintain a relatively large area, to ensure that the capacitor structure 15 has a relatively large filling area, and the capacitor structure 15 has a relatively large capacitance value. In addition, because the total area of the first gap hole 120 on the substrate 10 slightly increases, the efficiency of removing the first sacrificial layer 21 in a semiconductor preparation procedure can be further improved, thereby improving the production efficiency.

It should be noted that, the semiconductor structure and the preparation method therefor provided in the embodiments of the present disclosure may be applied to a DRAM structure or another semiconductor device. No further limitation is imposed herein. The embodiments of the semiconductor structure and the embodiments of the preparation method for a semiconductor structure provided in the present disclosure belong to the same concept. The technical features in the technical solutions described in the embodiments may be arbitrarily combined when there is no conflict.

The foregoing is merely preferred embodiments of the present disclosure, and is not intended to limit the protection scope of the present disclosure. Any modification, equivalent replacement, improvement, and the like made within the spirit and principle of the present disclosure shall fall within the protection scope of the present disclosure.

What is claimed is:

1. A semiconductor structure, comprising:
a substrate, the substrate comprising an array region;
a support structure, the support structure comprising a first support layer; the first support layer comprising first sub-holes and second sub-holes; the first sub-holes being distributed on an edge of the array region, and surrounding the second sub-holes; and a projection area of each of the first sub-holes on a plane of the substrate being less than a projection area of each of the second sub-holes on the plane of the substrate;
capacitor holes penetrating the support structure; and
capacitor structures formed by filling the capacitor holes.

2. The structure according to claim 1, wherein
in a direction perpendicular to the plane of the substrate, a projection of each of the first sub-holes overlaps projections of two of the capacitor holes, and a projection of each of the second sub-holes overlaps projections of three of the capacitor holes.

3. The structure according to claim 1, wherein
the projection area of each of the second sub-holes on the plane of the substrate is 1.8-2.2 times the projection area of each of the first sub-holes on the plane of the substrate.

4. The structure according to claim 1, wherein
in a direction perpendicular to the plane of the substrate, a projection of each of the first sub-holes overlaps projections of two of the capacitor holes, and a projection of each of the second sub-holes overlaps projections of four of the capacitor holes.

5. The structure according to claim 1, wherein
the projection area of each of the second sub-holes on the plane of the substrate is 2.8-3.2 times the projection area of each of the first sub-holes on the plane of the substrate.

6. The structure according to claim 1, wherein each of the capacitor structures comprises:
a first electrode layer, covering a sidewall and a bottom surface of each of the capacitor holes;
a capacitor dielectric layer, covering bare surfaces of the first electrode layer and the support structure, and covering sidewalls and bottom surfaces of each of the first sub-holes and each of the second sub-holes; and
a second electrode layer, covering a surface of the capacitor dielectric layer.

7. The structure according to claim 6, wherein the support structure further comprises a second support layer; and a thickness of the first support layer is greater than a thickness of the second support layer; and
the first support layer is located on an upper surface of the substrate and is connected to a part of a sidewall of the first electrode layer; and the second support layer is disposed parallel to the first support layer, and is connected to a part of the sidewall of the first electrode layer.

8. The structure according to claim 1, further comprising:
a protective layer, the protective layer covering a top and a sidewall of each of the capacitor structures, wherein a material of the protective layer comprises polysilicon.

9. A preparation method for a semiconductor structure, comprising:
providing a substrate, the substrate comprising an array region;
forming a stacked structure, the stacked structure comprising a first sacrificial layer and a first support layer sequentially stacked in a direction away from the substrate;
forming capacitor holes penetrating the stacked structure;
forming a first electrode layer on an inner wall of each of the capacitor holes;
forming a first gap hole penetrating the first support layer, the first gap hole comprising first sub-holes and second sub-holes; the first sub-holes being distributed on an edge of the array region and surrounding the second sub-holes, a projection area of each of the first sub-holes on a plane of the substrate being less than a projection area of each of the second sub-holes on the plane of the substrate; and
removing the first sacrificial layer through the first gap hole, to expose the first electrode layer.

10. The method according to claim 9, wherein in a direction perpendicular to the plane of the substrate, a projection of each of the first sub-holes overlaps projections of two of the capacitor holes, and a projection of each of the second sub-holes overlaps projections of three of the capacitor holes.

11. The method according to claim 9, wherein
the projection area of each of the second sub-holes on the plane of the substrate is 1.8-2.2 times the projection area of each of the first sub-holes on the plane of the substrate.

12. The method according to claim 9, wherein
in a direction perpendicular to the plane of the substrate, a projection of each of the first sub-holes overlaps projections of two of the capacitor holes, and a projection of each of the second sub-holes overlaps projections of four of the capacitor holes.

13. The method according to claim 9, wherein
the projection area of each of the second sub-holes on the plane of the substrate is 2.8-3.2 times the projection area of each of the first sub-holes on the plane of the substrate.

14. The method according to claim 9, wherein the forming the stacked structure further comprises:
forming a second sacrificial layer and a second support layer that are located between the substrate and the first sacrificial layer;
the second sacrificial layer being located between the substrate and the second support layer.

15. The method according to claim 14, further comprising:
forming, after the first sacrificial layer is removed through the first gap hole, a second gap hole penetrating the second support layer, wherein a projection of the second gap hole on the plane of the substrate is located in a projection of the first gap hole on the plane of the substrate; and
removing the second sacrificial layer through the second gap hole, to expose a remaining part of the first electrode layer.

16. The method according to claim 9, further comprising:
sequentially forming a capacitor dielectric layer covering the first electrode layer and a second electrode layer, to form a capacitor structure.

17. The method according to claim 9, wherein after the capacitor structure is formed, the method further comprises:
forming a protective layer, the protective layer covering a top and a sidewall of the capacitor structure.
